(19) United States
(12) Patent Application Publication
(10) Pub. No.: US 2014/0191264 A1
(43) Pub. Date: Jul. 10, 2014

(54) SEMICONDUCTOR LIGHT-EMITTING DEVICE

(71) Applicant: SAMSUNG ELECTRONICS CO., LTD., Suwon-Si (KR)

(72) Inventors: Jung-Sub KIM, Hwaseong-Si (US); Kyung-Wook HWANG, Gyeonggi-do (KR); Deok-Kyu KIM, Suwon (KR); Cheol-Soo SONE, Seoul (KR)

(73) Assignee: SAMSUNG ELECTRONICS CO., LTD., Suwon-Si (KR)

(21) Appl. No.: 14/034,391

(22) Filed: Sep. 23, 2013

(30) Foreign Application Priority Data
Jan. 7, 2013 (KR) 10-2013-0001788

(51) Int. Cl. H01L 33/58

(52) U.S. Cl. CPC H01L 33/58
USPC 257/98

(57) ABSTRACT

There is provided a semiconductor light-emitting device including a substrate having a first refractive index, a nitride semiconductor layer formed on the substrate and having a second refractive index that is different from the first refractive index, a light-emitting structure formed on the nitride semiconductor layer and including a first conductive semiconductor layer, an active layer, and a second conductive semiconductor layer, and an optical extraction film disposed between the substrate and the nitride semiconductor layer and having a refractive index between the first refractive index and the second refractive index.

### CROSS-REFERENCE TO RELATED APPLICATIONS

This application claims the benefit to Korean Patent Application No. 10-2013-0001788, filed on Jan. 7, 2013, in the Korean Intellectual Property Office, the disclosure of which is incorporated herein in its entirety by reference.

### TECHNICAL FIELD

One or more embodiments of the present inventive concept relates to a semiconductor light-emitting device, and in particular, a semiconductor light-emitting device including a nitride semiconductor thin film bonded onto a heterogeneous substrate.

### BACKGROUND

Light-emitting diodes using nitride semiconductor (nitride semiconductor light-emitting devices) are widely used in various light sources used for back light, illuminations, signal devices, and large-scale displays. To form a light-emitting device including an InGaAlN-based active layer, a nitride semiconductor thin film is bonded to a heterogeneous substrate, such as a sapphire substrate or a silicon substrate, and then, films for forming a light-emitting device on the nitride semiconductor thin film are grown thereon. However, in techniques disclosed, due to a difference in refractive indexes of a bonding layer for bonding the nitride semiconductor thin film to the heterogeneous substrate and the nitride semiconductor thin film, optical extraction efficiency decreases.

### SUMMARY

The inventive concept provides a semiconductor light-emitting device having such a structure that a decrease in optical extraction efficiency due to a bonding portion between a heterogeneous substrate and a nitride semiconductor thin film is prevented.

According to an aspect of the inventive concept, there is provided a semiconductor light-emitting device including: a substrate having a first refractive index, a nitride semiconductor layer disposed on the substrate and having a second refractive index that is different from the first refractive index, a light-emitting structure disposed on the nitride semiconductor layer and including a first conductive semiconductor layer, an active layer, and a second conductive semiconductor layer, and an optical extraction film disposed between the substrate and the nitride semiconductor layer and having a refractive index between the first refractive index and the second refractive index.

The optical extraction film may include a plurality of bonding layers having different refractive indexes included in a range from the first refractive index to the second refractive index, and the bonding layers are stacked from the substrate to the nitride semiconductor layer in such a sequence that a bonding layer with a larger refractive index is disposed closer to the nitride semiconductor layer.

The first refractive index is smaller than the second refractive index, the optical extraction film includes a plurality of bonding layers with different refractive indexes, and the bonding layers are stacked from the substrate to the nitride semiconductor layer in such a sequence that a bonding layer with a larger refractive index is disposed closer to the nitride semiconductor layer. The bonding layers of the optical extraction film are stacked in such a way that a refractive index increases in the form of a step structure in a thickness direction of the optical extraction film from the substrate to the nitride semiconductor layer.

The optical extraction film includes a plurality of bonding layers with different refractive indexes, and the plurality of bonding layers includes a bottom surface bonding layer having the smallest refractive index among the plurality of bonding layers and contacts the substrate, a top surface bonding layer having the largest refractive index among the plurality of bonding layers and being in contact with the nitride semiconductor layer, and a middle bonding layer having a refractive index between a refractive index of the bottom surface bonding layer and a refractive index of the top surface bonding layer and being disposed between the bottom surface bonding layer and the top surface bonding layer.

The bottom surface bonding layer, the top surface bonding layer, and the middle bonding layer have identical thicknesses. The bottom surface bonding layer, the top surface bonding layer, and the middle bonding layer have different thicknesses. From among the bottom surface bonding layer, the top surface bonding layer, and the middle bonding layer, the middle bonding layer has the largest thickness.

The extraction film includes a plurality of bonding layers with different refractive indexes, and at least one bonding layer of the plurality of bonding layers includes a plurality of island patterns that are spaced apart from each other.

The optical extraction film includes a plurality of bonding layers with different refractive indexes, and at least a portion of at least one bonding layer of the plurality of bonding layers has an uneven pattern.

The optical extraction film includes has a graded refractive index (GRI) bonding layer with a GRI. The GRI bonding layer comprises a TiₓSi₁₋ₓO_{y} film (0.05≦x≦0.95 and 0.2≦y≦2), a TiOₓ film (0.2≦x≦2), a SiOₓ film (0.2≦x≦2), or a combination thereof.

According to an aspect of the inventive concept, there is provided a semiconductor light-emitting device including: a substrate, an optical extraction film being in contact with a surface of the substrate and including at least one bonding layer having a refractive index that is larger than a refractive index of the substrate, a nitride semiconductor layer being in contact with a surface of the optical extraction film and having a refractive index that is equal to or larger than a refractive index of a portion of the optical extraction film of which refractive index is the largest from among all the portions of the optical extraction film, and a light-emitting structure formed on the nitride semiconductor layer and including a first conductive semiconductor layer, an active layer, and a second conductive semiconductor layer.

The optical extraction film includes a plurality of bonding layers with different refractive indexes included in a range that is larger than the refractive index of the substrate and is equal to or smaller than the refractive index of the nitride semiconductor layer, and the plurality of bonding layers are stacked from the substrate to the nitride semiconductor layer in such a sequence that a bonding layer with a larger refractive index is disposed closer to the nitride semiconductor layer.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional view of essential parts of a semiconductor light-emitting device according to some embodiments of the present inventive concept;

FIG. 2A is a cross-sectional view of an optical extraction film according to some embodiments of the present inventive concept that is employable as an optical extraction film of the semiconductor light-emitting device of FIG. 1;

FIG. 2B shows a graph showing a refractive index difference in an exemplary structure including a substrate, the optical extraction film of FIG. 2A, and a nitride semiconductor thin film;

FIG. 2C is a cross-sectional view of the semiconductor light-emitting device of FIG. 1 including the optical extraction film of FIG. 2A as an optical extraction film;

FIG. 3A is a cross-sectional view of an optical extraction film according to some embodiments of the present inventive concept that is employable as an optical extraction film of the semiconductor light-emitting device of FIG. 1;

FIG. 3B shows a graph showing a refractive index difference in an exemplary structure including a substrate, the optical extraction film of FIG. 3A, and a nitride semiconductor thin film;

FIG. 3C is a cross-sectional view of the semiconductor light-emitting device of FIG. 1 including the optical extraction film of FIG. 3A as an optical extraction film;

FIG. 4A is a cross-sectional view of an optical extraction film according to some embodiments of the present inventive concept that is employable as an optical extraction film of the semiconductor light-emitting device of FIG. 1;

FIG. 4B shows a graph showing a refractive index difference in an exemplary structure including a substrate, the optical extraction film of FIG. 4A, and a nitride semiconductor thin film;

FIG. 5A is a cross-sectional view of an optical extraction film according to some embodiments of the present inventive concept that is employable as an optical extraction film of the semiconductor light-emitting device of FIG. 1;

FIG. 5B shows a graph showing a refractive index difference in an exemplary structure including a substrate, the optical extraction film of FIG. 5A, and a nitride semiconductor thin film;

FIG. 6A is a cross-sectional view of an optical extraction film according to some embodiments of the present inventive concept that is employable as an optical extraction film of the semiconductor light-emitting device of FIG. 1;

FIGS. 6B to 6E show graphs illustrating refractive index distributions in a GRI bonding layer illustrated in FIG. 6A;

FIG. 7 is a cross-sectional view of an optical extraction film according to some embodiments of the present inventive concept that is employable as an optical extraction film of the semiconductor light-emitting device of FIG. 1;

FIG. 8 is a cross-sectional view of an optical extraction film according to some embodiments of the present inventive concept that is employable as an optical extraction film of the semiconductor light-emitting device of FIG. 1;

FIG. 9 is a cross-sectional view of a semiconductor light-emitting device according to some embodiments of the present inventive concept;

FIGS. 10A to 10D are cross-sectional views for explaining a process for forming the semiconductor light-emitting device of FIG. 9, according to some embodiments of the present inventive concept; and

FIG. 11 is a diagram illustrating a dimming system including a nitride semiconductor light-emitting device according to some embodiments of the present inventive concept.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

The inventive concept will now be described more fully with reference to the accompanying drawings, in which exemplary embodiments of the inventive concept are shown. The same elements in the drawings are denoted by the same reference numerals and a repeated explanation thereof will be omitted.

The inventive concept now will be described more fully hereinafter with reference to the accompanying drawings, in which elements of the inventive concept are shown. The inventive concept may, however, be embodied in many different forms and should not be construed as limited to the exemplary embodiments set forth herein. Rather, these embodiments are provided so that this disclosure will be thorough and complete, and will fully convey the scope of the inventive concept to one of ordinary skill in the art.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept. For example, a first element may be named a second element and similarly a second element may be named a first element without departing from the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In other embodiments, a specific order of processes may be changed. For example, two processes which are continuously explained may be substantially simultaneously performed and may be performed in an order opposite to that explained.

Variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing.

As used herein, the term “and/or” includes any and all combinations of one or more of the associated listed items. Expressions such as “at least one of,” when preceding a list of elements, modify the entire list of elements and do not modify the individual elements of the list.

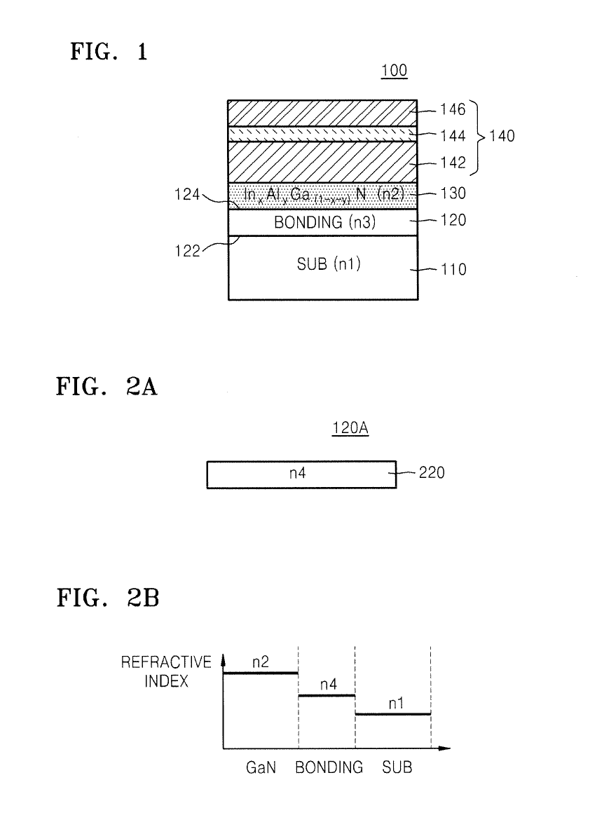

FIG. 1 is a cross-sectional view of essential parts of a semiconductor light-emitting device 100 according to some embodiments of the present inventive concept.

Referring to FIG. 1, the semiconductor light-emitting device 100 includes a substrate 110, an optical extraction film 120 contacting a surface of the substrate 110, a nitride semiconductor thin film 130 contacting a surface of the optical extraction film 120, and a light-emitting structure 140 formed on the nitride semiconductor thin film 130.

The substrate 110 may be a transparent substrate having a first refractive index n1. For example, the substrate 110 may be formed of sapphire (Al₂O₃), gallium oxide (Ga₂O₃), lithium gallium oxide (LiGaO₂), lithium aluminum oxide (LiAlO₂), or magnesium aluminum oxide (MgAl₂O₄).

The nitride semiconductor thin film 130 may have a second refractive index n2 that is different from the first refractive index n1. In some embodiments, the second refractive index n2 of the nitride semiconductor thin film 130 may be larger than the first refractive index n1.

The nitride semiconductor thin film 130 may be formed of a gallium nitride-based compound semiconductor represented by InₓAl_{y}Ga_{(1-x-y)}N(0≦x≦1, 0≦y≦1, and 0≦x+y≦1). In some embodiments, the nitride semiconductor thin film 130 may be formed of a GaN monocrystal.

The optical extraction film 120 interposed between the substrate 110 and the nitride semiconductor thin film 130 may have a bottom surface 122 contacting the substrate 110 and a top surface 124 contacting the nitride semiconductor thin film 130. The optical extraction film 120 may include at least one bonding layer having a third refractive index n3 between the first refractive index n1 and the second refractive index n2.

The optical extraction film 120 is disposed between the substrate 110 and the nitride semiconductor thin film 130 to attach the substrate 110 and the nitride semiconductor thin film 130 to each other. The optical extraction film 120 has a refractive index between a refractive index of the substrate 110 and a refractive index of the nitride semiconductor thin film 130, thereby preventing optical loss caused by a reflective light occurring when there is a large difference in a refractive index between the nitride semiconductor thin film 130 and a film disposed on an optical pathway to the substrate 110.

The light-emitting structure 140 formed on the nitride semiconductor thin film 130 may include a first conductive semiconductor layer 142, an active layer 144, and a second conductive semiconductor layer 146, each formed of a gallium nitride-based compound semiconductor represented by InₓAl_{y}Ga_{(1-x-y)}N(0≦x≦1, 0≦y≦1, and 0≦x+y≦1). In some embodiments, the first conductive semiconductor layer 142 may include an n-type GaN layer, and the second conductive semiconductor layer 146 may include a p-type GaN layer. The n-type impurity included in the n-type GaN layer may be Si, Ge, Sn, or the like. The p-type impurity included in the p-type GaN layer may be Mg, Zn, Be, or the like. The active layer 144 may emit light with a predetermined intensity of energy due to the recombination of electrons and holes. The active layer 144 may have at least one alternate structure of a quantum well layer and a quantum barrier layer. The quantum well layer may have a single quantum well structure or a multi-quantum well structure. In some embodiments, the active layer 144 may be formed of u-AlGaN. In other embodiments, the active layer 144 may have a multi-quantum well structure of GaN/AlGaN, InAlGaN/InAlGaN, or InGaN/AlGaN. To improve light-emitting efficiency of the active layer 144, the depth of the quantum well, the stack number of pairs of quantum well layers and quantum barrier layers, and thicknesses of the quantum well layer and the quantum barrier layer in the active layer 144 may be varied.

In some embodiments, the light-emitting structure 140 may be formed by metal-organic chemical vapor deposition (MOCVD), hydride vapor phase epitaxy (HVPE), or molecular beam epitaxy (MBE).

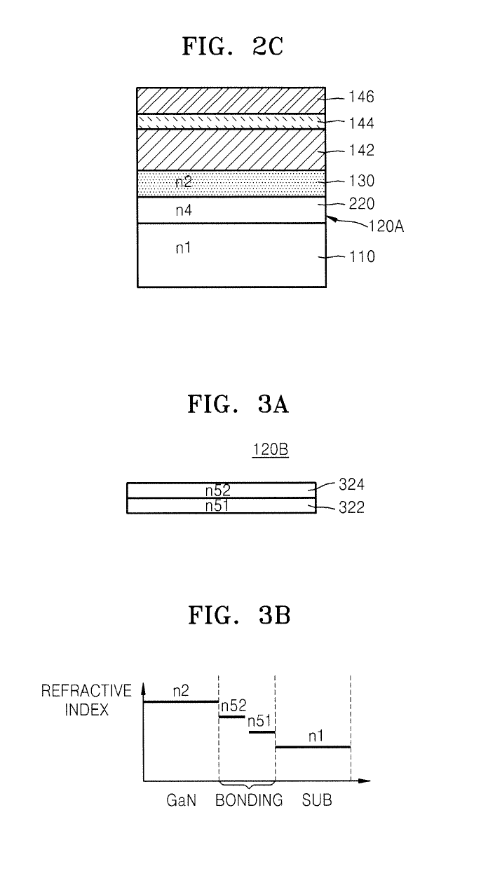

FIG. 2A is a cross-sectional view of an optical extraction film 120A according to some embodiments of the present inventive concept that is employable as the optical extraction film 120 of the semiconductor light-emitting device 100 of FIG. 1.

The optical extraction film 120A may comprise a bonding layer 220 with a refractive index n4 that is larger than the first refractive index n1 of the substrate 110 illustrated in FIG. 1 and the second refractive index n2 of the nitride semiconductor thin film 130 illustrated in FIG. 1.

FIG. 2B shows a graph showing a refractive index difference in an exemplary structure including the substrate 110, the optical extraction film 120A, and the nitride semiconductor thin film 130.

As illustrated in FIG. 2B, in the semiconductor light-emitting device 100 of FIG. 1, the nitride semiconductor thin film 130 may include a GaN monocrystalline layer and the optical extraction film 120 may be the optical extraction film 120A illustrated in FIG. 2A. The nitride semiconductor thin film 130 including a GaN monocrystalline layer may have a refractive index of about 2.48692 at a wavelength of 450 nm. When the substrate 110 is formed of sapphire, the substrate 110 may have a refractive index of about 1.77937 at a wavelength of 450 nm. The bonding layer 220 that constitutes the optical extraction film 120A may have a refractive index that is larger than the refractive index of sapphire and is smaller than the refractive index of the GaN monocrystalline layer. For example, the bonding layer 220 may include a SiO₂, Ta₂O₅, HfO₂, ZnO, ZrO₂, or SiOₓN_{y} film (x+y≦2, x>0, and y>0). At a wavelength of 450 nm, a SiO₂ film may have a refractive index of about 1.55248, a Ta₂O₅ film may have a refractive index of about 1.83236, a HfO₂ film may have a refractive index of about 1.9597, a ZnO film may have a refractive index of about 2.1054, and ZrO₂ film may have a refractive index of about 2.23884. A SiOₓN_{y} film may have a refractive index of about 1.49 to about 1.92 at a wavelength of 450 nm according to a nitrogen (N) content, and the larger refractive index, the larger N content.

The bonding layer 220 may be formed by chemical vapor deposition (CVD), plasma-enhanced CVD (PECVD), high density plasma-enhanced chemical vapor deposition (HD-PECVD), atomic layer deposition (ALD), plasma-enhanced atomic layer deposition (PEALD), or physical vapor deposition (PVD). In some embodiments, during a deposition process for the bonding layer 220, a refractive index of the bonding layer 220 may be controlled by adjusting power of a radio frequency (RF) and a deposition temperature.

FIG. 2C is a cross-sectional view of the semiconductor light-emitting device 100 of FIG. 1 that includes the optical extraction film 120A of FIG. 2A as the optical extraction film 120.

When light generated in the active layer 144 progresses from the nitride semiconductor thin film 130 having a relatively large refractive index to the substrate 110 with a refractive index that is smaller than the refractive index of the nitride semiconductor thin film 130, even when a difference in the refractive indexes of the nitride semiconductor thin film 130 and the substrate 110 is large, due to the presence of the optical extraction film 120A including the bonding layer 220 with a refractive index between the refractive index n1 of the substrate 110 and the refractive index n2 of the nitride semiconductor thin film 130, it is highly likely that an incident angle of light generated in the active layer 144 progressing from the nitride semiconductor thin film 130 to the substrate 110 through the optical extraction film 120A may be smaller than a critical angle that is an angle at which total reflection occurs. Accordingly, the most of light progressing from the active layer 144 to the nitride semiconductor thin film 130 is refracted into the optical extraction film 120A without reflection and is extracted toward the outside the substrate 110. Accordingly, when light from the active layer 144 arrives the substrate 110 from the nitride semiconductor thin film 130 through the optical extraction film 120A, a pathway of light that is extracted from the nitride semiconductor thin film 130 to the outside through the substrate 110 may be reduced, optical loss may be suppressed, and optical extraction efficiency may improve.

FIG. 2A illustrates the optical extraction film 120A including the single bonding layer 220 as the optical extraction film 120 of FIG. 1. However, embodiments of the present inventive concept are not limited thereto. The optical extraction film 120 may have a multi-layer structure including a plurality of bonding layers.

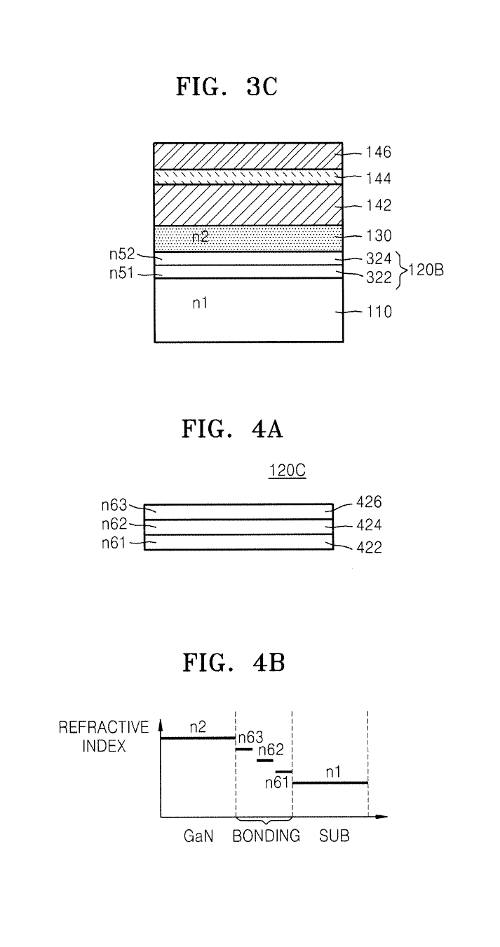

FIG. 3A is a cross-sectional view of an optical extraction film 120B according to some embodiments of the present inventive concept that is employable as the optical extraction film 120 of the semiconductor light-emitting device 100 of FIG. 1.

The optical extraction film 120B may include a first bonding layer 322 and a second bonding layer 324, which have different refractive indexes.

The first bonding layer 322 and the second bonding layer 324 respectively have refractive indexes n51 and n52 that are larger than the first refractive index n1 of the substrate 110 illustrated in FIG. 1, and smaller than the second refractive index n2 of the nitride semiconductor thin film 130. The refractive index n51 of the first bonding layer 322 may be different from the refractive index n52 of the second bonding layer 324.

FIG. 3B shows a graph showing a refractive index difference in an exemplary structure including the substrate 110, the optical extraction film 120B, and the nitride semiconductor thin film 130.

As illustrated in FIG. 3B, in the semiconductor light-emitting device 100 of FIG. 1, the substrate 110 may be formed of sapphire, the nitride semiconductor thin film 130 may include a GaN monocrystalline layer, and the optical extraction film 120 may be the optical extraction film 120B illustrated in FIG. 3A. The first bonding layer 322 and the second bonding layer 324 that constitute the optical extraction film 120B may have a refractive index that is larger than the refractive index of sapphire and is smaller than the refractive index of the GaN monocrystalline layer. The first bonding layer 322 and the second bonding layer 324 may be sequentially stacked in a direction from the substrate 110 to the nitride semiconductor thin film 130 in such a way that a bonding layer closer to the nitride semiconductor thin film 130 has a larger refractive index.

For example, the first bonding layer 322 and the second bonding layer 324 may each be formed of different materials selected from a SiO₂, Ta₂O₅, HfO₂, ZnO, ZrO₂, and SiOₓN_{y} film (x+y≦2, x>0, and y>0).

FIG. 3C is a cross-sectional view of the semiconductor light-emitting device 100 of FIG. 1 that includes the optical extraction film 120C of FIG. 3A as the optical extraction film 120.

When light generated in the active layer 144 progresses from the nitride semiconductor thin film 130 having a relatively large refractive index to the substrate 110 with a refractive index that is smaller than the refractive index of the nitride semiconductor thin film 130, even when a difference in the refractive indexes of the nitride semiconductor thin film 130 and the substrate 110 is large, due to the presence of the optical extraction film 120B including the first bonding layer 322 and the second bonding layer 324 having the refractive indexes n51 and n52 between the refractive index n1 of the substrate 110 and the refractive index n2 of the nitride semiconductor thin film 130, it is highly likely that an incident angle of light generated in the active layer 144 progressing from the nitride semiconductor thin film 130 to the substrate 110 through the optical extraction film 120B may be smaller than a critical angle that is an angle at which total reflection occurs. Accordingly, the most of light progressing from the active layer 144 to the nitride semiconductor thin film 130 is refracted into the optical extraction film 120 without reflection and is extracted toward the outside the substrate 110. Accordingly, when light from the active layer 144 arrives the substrate 110 from the nitride semiconductor thin film 130 through the optical extraction film 120B, a pathway of light that is extracted from the nitride semiconductor thin film 130 to the outside through the substrate 110 may be reduced, optical loss may be suppressed, and optical extraction efficiency may improve.

FIG. 4A is a cross-sectional view of an optical extraction film 120C according to some embodiments of the present inventive concept that is employable as the optical extraction film 120 of the semiconductor light-emitting device 100 of FIG. 1.

The optical extraction film 120C may include a first bonding layer 422, a second bonding layer 424, and a third bonding layer 426, which have different refractive indexes.

The first bonding layer 422, the second bonding layer 424, and the third bonding layer 426 respectively have refractive indexes n61, n62, n63 that are larger than the first refractive index n1 of the substrate 110 illustrated in FIG. 1 and smaller than the second refractive index n2 of the nitride semiconductor thin film 130. The refractive indexes n61, n62, n63 of the first bonding layer 422, the second bonding layer 424, and the third bonding layer 426 may be different from each other. In some embodiments, the first bonding layer 422, the second bonding layer 424, and the third bonding layer 426 may have a substantially identical thickness, but are not limited thereto.

FIG. 4B shows a graph showing a refractive index difference in an exemplary structure including the substrate 110, the optical extraction film 120C, and the nitride semiconductor thin film 130.

As illustrated in FIG. 4B, in the semiconductor light-emitting device 100 of FIG. 1, the substrate 110 may be formed of sapphire, the nitride semiconductor thin film 130 may include a GaN monocrystalline layer, and the optical extraction film 120 may be the optical extraction film 120C illustrated in FIG. 4A. The first bonding layer 422, the second bonding layer 424, and the third bonding layer 426 that constitute the optical extraction film 120C may have a refractive index that is larger than the refractive index of sapphire and is smaller than the refractive index of the GaN monocrystalline layer. The first bonding layer 422, the second bonding layer 424, and the third bonding layer 426 may be sequentially stacked in a direction from the substrate 110 to the nitride semiconductor thin film 130 in such a way that a bonding layer closer to the nitride semiconductor thin film 130 has a larger refractive index.

For example, the first bonding layer 422, the second bonding layer 424, and the third bonding layer 426 may each be formed of different materials selected from a SiO₂, Ta₂O₅, HfO₂, ZnO, ZrO₂, or SiOₓN_{y} film (x+y≦2, x>0, and y>0).

When the optical extraction film 120C of FIG. 4A is used, as described in connection with FIGS. 2C and 3C, when light from the active layer 144 arrives the substrate 110 from the nitride semiconductor thin film 130 through the optical extraction film 120C, a pathway of light that is extracted from the nitride semiconductor thin film 130 to the outside through the substrate 110 may be reduced, optical loss may be suppressed, and optical extraction efficiency may improve.

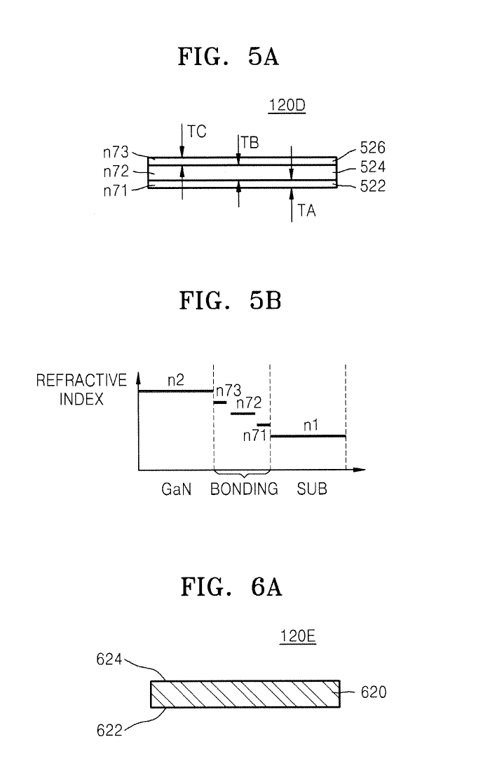

FIG. 5A is a cross-sectional view of an optical extraction film 120D according to some embodiments of the present inventive concept that is employable as the optical extraction film 120 of the semiconductor light-emitting device 100 of FIG. 1.

The optical extraction film 120C may include a first bonding layer 522, a second bonding layer 524, and a third bonding layer 526, which have different refractive indexes.

The first bonding layer 522, the second bonding layer 524, and the third bonding layer 526 respectively have refractive indexes n71, n72, and n73 that are larger than the first refractive index n1 of the substrate 110 illustrated in FIG. 1 and smaller than the second refractive index n2 of the nitride semiconductor thin film 130. The refractive indexes n71, n72, and n73 of the first bonding layer 522, the second bonding layer 524, and the third bonding layer 526 may be different from each other. In some embodiments, the first bonding layer 522, the second bonding layer 524, and the third bonding layer 526 may have different thicknesses TA, TB, and TC. In other embodiments, from among the first bonding layer 522, the second bonding layer 524, and the third bonding layer 526, the second bonding layer 524 disposed between the first bonding layer 522 and the third bonding layer 526 may have the largest thickness. Also, a thickness TA of the first bonding layer 522 and a thickness TC of the third bonding layer 526 may be smaller than the thickness TB of the second bonding layer 524. In other embodiments, the thickness TA of the first bonding layer 522 may be the same as the thickness TC of the third bonding layer 526. However, the present inventive concept is not limited to the exemplary structures, the first bonding layer 522, the second bonding layer 524, and the third bonding layer 526 may have various thicknesses.

FIG. 5B shows a graph showing a refractive index difference in an exemplary structure including the substrate 110, the optical extraction film 120D, and the nitride semiconductor thin film 130.

As illustrated in FIG. 5B, in the semiconductor light-emitting device 100 of FIG. 1, the substrate 110 may be formed of sapphire, the nitride semiconductor thin film 130 may include a GaN monocrystalline layer, and the optical extraction film 120 may be the optical extraction film 120C illustrated in FIG. 5A. The first bonding layer 522, the second bonding layer 524, and the third bonding layer 526 that constitute the optical extraction film 120D may have a refractive index that is larger than the refractive index of sapphire and is smaller than the refractive index of the GaN monocrystalline layer. The first bonding layer 522, the second bonding layer 524, and the third bonding layer 526 may be sequentially stacked in a direction from the substrate 110 to the nitride semiconductor thin film 130 in such a way that a bonding layer closer to the nitride semiconductor thin film 130 has a larger refractive index.

For example, the first bonding layer 522, the second bonding layer 524, and the third bonding layer 526 may each be formed of different materials selected from a SiO₂, Ta₂O₅, HfO₂, ZnO, ZrO₂, or SiOₓN_{y} film (x+y≦2, x>0, and y>0).

When the optical extraction film 120D of FIG. 5A is used, like described in connection with FIGS. 2C and 3C, when light from the active layer 144 arrives the substrate 110 from the nitride semiconductor thin film 130 through the optical extraction film 120D, a pathway of light that is extracted from the nitride semiconductor thin film 130 to the outside through the substrate 110 may be reduced, optical loss may be suppressed, and optical extraction efficiency may improve.

Bonding layers that constitute the optical extraction films 120B, 120C, and 120D of FIGS. 3A, 4A and 5A have refractive indexes that increase in the form of a step structure in the direction from the substrate 110 to the nitride semiconductor thin film 130 illustrated in FIG. 1. However, the present inventive concept is not limited thereto. According to an embodiment of the present inventive concept, the optical extraction film 120 illustrated in FIG. 1 may include a GRI bonding layer having a graded refractive index (GRI).

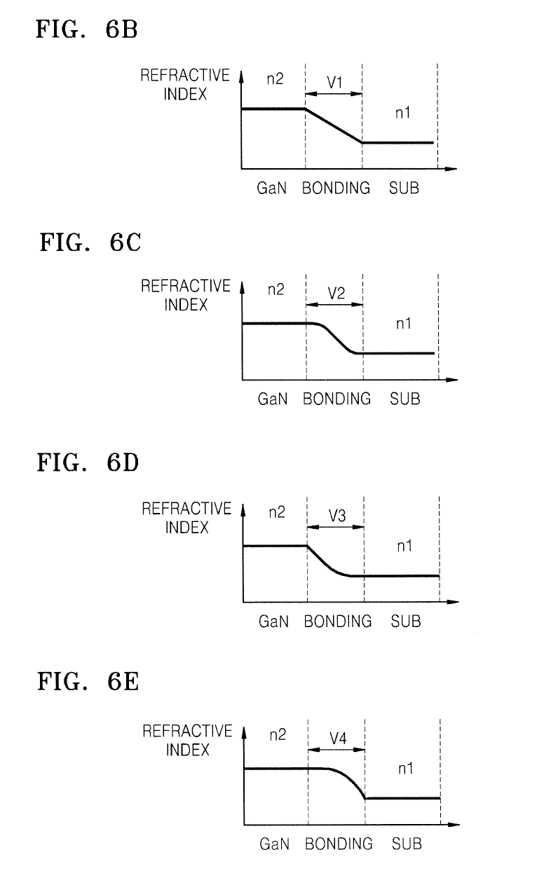

FIG. 6A is a cross-sectional view of an optical extraction film 120E according to some embodiments of the present inventive concept that is employable as the optical extraction film 120 of the semiconductor light-emitting device 100 of FIG. 1.

The optical extraction film 120E may include a GRI bonding layer 620 with a refractive index that continuously changes between the first refractive index n1 of the substrate 110 illustrated in FIG. 1 and the second refractive index n2 of the nitride semiconductor thin film 130 illustrated in FIG. 1.

The GRI bonding layer 620 may be formed of a TiₓSi₁₋ₓO_{y} film (0.05≦x≦0.95, 0.2≦y≦2), a TiOₓ film (0.2≦x≦2), a SiOₓ film (0.2≦x≦2), or a combination thereof.

When the GRI bonding layer 620 includes a TiₓSi₁₋ₓO_{y} film, the larger Ti content in the TiₓSi₁₋ₓO_{y} film, the TiₓSi₁₋ₓO_{y} film may have the larger refractive index. Accordingly, in the GRI bonding layer 620, a portion of the GRI bonding layer 620 closer to a bottom surface 622 of the GRI bonding layer 620 may have a lower Ti content in the TiₓSi₁₋ₓO_{y} film, and a portion of the GRI bonding layer 620 closer to a top surface 624 of the GRI bonding layer 620 may have a larger Ti content in the TiₓSi₁₋ₓO_{y} film.

In some embodiments, a TiₓSi₁₋ₓO_{y} film that constitutes the GRI bonding layer 620 may be formed by plasma-enhanced atomic layer deposition (PEALD). For example, a first atomic layer depostion (ALD) cycle for forming atom layers of TiO₂ having a relatively great refractive index, and a second ALD cycle for forming atom layers of SiO₂ having a relatively low refractive index are alternately performed, and the refractive index and thickness of the GRI bonding layer 620 may be controlled by adjusting a ratio of the number of first ALD cycles to the number of the second ALD cycles. When the number of second ALD cycles is larger than the number of first ALD cycles, the Si content increases and thus, the refractive index may be relatively small. On the other hand, when the number of first ALD cycles is larger than the number of second ALD cycles, the Ti content increases and thus, the refractive index may be relatively great.

In some embodiments, the GRI bonding layer 620 may have a stack structure including a SiOₓ film, a TiₓSi₁₋ₓO_{y} film, and a TiOₓ film, which are sequentially stacked. In this regard, a SiOₓ film is first formed to constitute the bottom surface 622 of the GRI bonding layer 620, and then, a TiₓSi₁₋ₓO_{y} film and a TiOₓ film are sequentially formed thereon. By doing so, the GRI bonding layer 620 may have an increasing refractive index in a thickness direction thereof from the bottom surface 622 to the top surface 624 of the GRI bonding layer 620.

In other embodiments, the TiₓSi₁₋ₓO_{y} film of the GRI bonding layer 620 may be formed by sputtering. For example, in a sputtering chamber containing a TiₓSi₁₋ₓO_{y} target, the GRI bonding layer 620 may be formed in the presence of a reactive gas comprising argon (Ar) gas, oxygen (O₂) gas, nitrogen (N₂) gas, or a combination thereof. An atom ratio or weight ratio of Ti to Si in the TiₓSi₁₋ₓO_{y} target may be controlled by changing x value of the TiₓSi₁₋ₓO_{y} target. When the x value of the TiₓSi₁₋ₓO_{y} target decreases, the Si content increases and thus, the refractive index may relatively decrease, and when the x value increases, the Ti content increases and thus, the refractive index may relatively increase.

When the GRI bonding layer 620 includes a SiOₓN_{y} film, the larger N content in the SiOₓN_{y} film, the SiOₓN_{y} film may have a larger refractive index. Accordingly, in the GRI bonding layer 620, a portion of the GRI bonding layer 620 closer to a bottom surface 622 of the GRI bonding layer 620 may have a lower N content in the SiOₓN_{y} film, and a portion of the GRI bonding layer 620 closer to a top surface 624 of the GRI bonding layer 620 may have a larger N content in the TiₓSi₁₋ₓO_{y} film.

FIGS. 6B to 6E show graphs illustrating refractive index distributions in the GRI bonding layer 620 illustrated in FIG. 6A.

Referring to FIG. 6B, in the semiconductor light-emitting device 100 of FIG. 1, the nitride semiconductor thin film 130 may include a GaN monocrystalline layer and the optical extraction film 120 may be the optical extraction film 120E illustrated in FIG. 6A. The GRI bonding layer 620 that constitutes the optical extraction film 120E may have, as in section “V1”, a variable refractive index that continuously changes at a constant variation rate from the first refractive index n1 to the second refractive index n2, from the bottom surface 622 of the GRI bonding layer 620 contacting the substrate 110 to the top surface 624 of the GRI bonding layer 620 contacting the nitride semiconductor thin film 130 in the thickness direction of the GRI bonding layer 620.

Referring to FIG. 6C, the GRI bonding layer 620 that constitutes the optical extraction film 120E may have the same structure as described in connection with FIG. 6B, except that as in section “V2”, although the GRI bonding layer 620 has a variable refractive index from the first refractive index n1 to the second refractive index n2, from the bottom surface 622 contacting the substrate 110 to the top surface 624 contacting the nitride semiconductor thin film 130 in the thickness direction of the GRI bonding layer 620, portions of the GRI bonding layer 620 near the bottom surface 622 and the top surface 624 may undergo a relatively small refractive index change, and a central portion of GRI bonding layer 620 may undergo a relatively large refractive index change.

Referring to FIG. 6D, the GRI bonding layer 620 that constitutes the optical extraction film 120E may have the same structure as described in connection with FIG. 6B, except that as in section “V3”, although the GRI bonding layer 620 has variable a refractive index from the first refractive index n1 to the second refractive index n2, from the bottom surface 622 contacting the substrate 110 to the top surface 624 contacting the nitride semiconductor thin film 130 in the thickness direction of the GRI bonding layer 620, a portion of the GRI bonding layer 620 near the bottom surface 622 may undergo a relatively small refractive index change, and a central portion of GRI bonding layer 620 and a portion of the GRI bonding layer 620 near the top surface 624 thereof may undergo a relatively large refractive index change.

Referring to FIG. 6E, the GRI bonding layer 620 that constitutes the optical extraction film 120E may have the same structure as described in connection with FIG. 6B, except that as in section “V4”, although the GRI bonding layer 620 has a variable refractive index from the first refractive index n1 to the second refractive index n2, from the bottom surface 622 contacting the substrate 110 to the top surface 624 contacting the nitride semiconductor thin film 130 in the thickness direction of the GRI bonding layer 620, a portion of the GRI bonding layer 620 near the bottom surface 622 may undergo a relatively large refractive index change, and a central portion of GRI bonding layer 620 and a portion of the GRI bonding layer 620 near the top surface 624 thereof may undergo a relatively small refractive index change.

When the optical extraction film 120E of FIG. 6A is used, like described in connection with FIGS. 2C and 3C, when light from the active layer 144 arrives the substrate 110 from the nitride semiconductor thin film 130 through the optical extraction film 120E, a pathway of light that is extracted from the nitride semiconductor thin film 130 to the outside through the substrate 110 may be reduced, optical loss may be suppressed, and optical extraction efficiency may be improved.

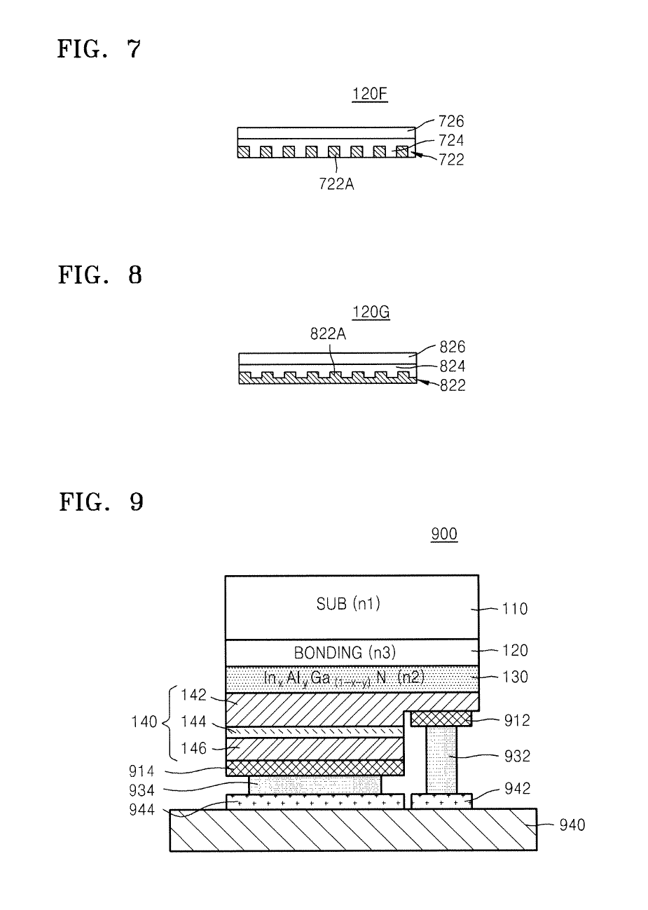

FIG. 7 is a cross-sectional view of an optical extraction film 120F according to some embodiments of the present inventive concept that is employable as the optical extraction film 120 of the semiconductor light-emitting device 100 of FIG. 1.

The optical extraction film 120F may include a first bonding layer 722, a second bonding layer 724, and a third bonding layer 726, which have different refractive indexes.

The first bonding layer 722, the second bonding layer 724, and the third bonding layer 726 respectively have refractive indexes that are larger than the first refractive index n1 of the substrate 110 illustrated in FIG. 1 and smaller than the second refractive index n2 of the nitride semiconductor thin film 130. The refractive indexes of the first bonding layer 722, the second bonding layer 724, and the third bonding layer 726 may be different from each other.

The first bonding layer 722 may include a plurality of island patterns 722A that are spaced from each other. However, the present inventive concept is not limited to the exemplary structure. According to the present inventive concept, at least one bonding layer of the first bonding layer 722, the second bonding layer 724, and the third bonding layer 726 may include a plurality of island patterns that are spaced from each other. For example, the second bonding layer 724 or the third bonding layer 726 may include a plurality of island patterns that are spaced from each other. Also, although the island patterns 722A of the first bonding layer 722 illustrated in FIG. 7 have the same shape and the same size, the present inventive concept is not limited thereto. The island pattern 722A may have various other shapes and sizes.

In some embodiments, the first bonding layer 722, the second bonding layer 724, and the third bonding layer 726 may each be formed of different materials selected from a SiO₂, Ta₂O₅, HfO₂, ZnO, ZrO₂, and SiOₓN_{y} film (x+y≦2, x>0, and y>0).

In some embodiments, the first bonding layer 722 formed of the island pattern 722A is formed as follows: first, a continuous film-type preliminary first bonding layer (not shown) is formed, and then, the preliminary first bonding layer is patterned by dry etching or wet etching.

When the optical extraction film 120F of FIG. 7 is used, like described in connection with FIGS. 2C and 3C, when light from the active layer 144 arrives the substrate 110 from the nitride semiconductor thin film 130 through the optical extraction film 120F, a pathway of light that is extracted from the nitride semiconductor thin film 130 to the outside through the substrate 110 may be reduced, optical loss may be suppressed, and optical extraction efficiency may improve. Also, since the optical extraction film 120F includes the first bonding layer 722 including the island pattern 722A, a critical angle may increase due to the island pattern 722A and thus, even when light generated in the active layer 144 enters the optical extraction film 120F at an angle that is larger than a critical angle, which is an angle at which total reflection may occur, light may transmit through the optical extraction film 120F without total reflection due to the island patterns 722A, entering the substrate 110. Accordingly, an optical extraction efficiency may be further improved.

FIG. 8 is a cross-sectional view of an optical extraction film 120G according to some embodiments of the present inventive concept that is employable as the optical extraction film 120 of the semiconductor light-emitting device 100 of FIG. 1.

The optical extraction film 120G may include a first bonding layer 822, a second bonding layer 824, and a third bonding layer 826, which have different refractive indexes.

The first bonding layer 822, the second bonding layer 824, and the third bonding layer 826 respectively have refractive indexes that are larger than the first refractive index n1 of the substrate 110 illustrated in FIG. 1 and smaller than the second refractive index n2 of the nitride semiconductor thin film 130. The refractive indexes of the first bonding layer 822, the second bonding layer 824, and the third bonding layer 826 may be different from each other. In some embodiments, at least a portion of at least one bonding layer of the first bonding layer 822, the second bonding layer 824, and the third bonding layer 826 may have an uneven structure. In FIG. 8, uneven patterns 822A are formed only in the first bonding layer 822. However, the present inventive concept is not limited thereto. For example, at least one of the second bonding layer 824 and the third bonding layer 826 may also have an uneven pattern. Also, although the uneven patterns 822A of the first bonding layer 822 illustrated in FIG. 8 have the same shape and the same size, the present inventive concept is not limited thereto. The uneven patterns 822A may have various other shapes and sizes.

In some embodiments, the first bonding layer 822, the second bonding layer 824, and the third bonding layer 826 may each be formed of different materials selected from a SiO₂, Ta₂O₅, HfO₂, ZnO, ZrO₂, and SiOₓN_{y} film (x+y≦2, x>0, and y>0).

In some embodiments, the first bonding layer 822 comprising the uneven patterns 822A is formed as follows: first, a continuous film-type preliminary first bonding layer (not shown) is formed, and then, the preliminary first bonding layer is etched by dry etching or wet etching in such a way that only a part of a total thickness is removed.

When the optical extraction film 120G of FIG. 8 is used, like described in connection with FIGS. 2C and 3C, when light from the active layer 144 arrives the substrate 110 from the nitride semiconductor thin film 130 through the optical extraction film 120G, a pathway of light that is extracted from the nitride semiconductor thin film 130 to the outside through the substrate 110 may be reduced, optical loss may be suppressed, and optical extraction efficiency may be improved. Also, since the optical extraction film 120G includes the first bonding layer 822 comprising the uneven patterns 822A, a critical angle may increase due to the uneven patterns 822A and thus, even when light generated in the active layer 144 enters the optical extraction film 120G at an angle that is larger than a critical angle, which is an angle at which total reflection may occur, light may transmit through the optical extraction film 120G to the substrate 110 without total reflection by virtue of the uneven patterns 822A. Accordingly, an optical extraction efficiency may be further improved.

FIG. 9 is a cross-sectional view of a semiconductor light-emitting device 900 according to some embodiments of the present inventive concept.

The semiconductor light-emitting device 900 illustrated in FIG. 9 has a flip-chip mounted vertical structure. In FIG. 9, the same reference numerals denote the same elements as those shown in FIG. 1, and the detailed description thereof are omitted herein to simplify the description.

Referring to FIG. 9, the semiconductor light-emitting device 900 includes an n-type electrode 912 formed on a first conductive semiconductor layer 142, and a p-type electrode 914 formed on a second conductive semiconductor layer 146. The n-type electrode 912 and the p-type electrode 914 are respectively connected to a first conductive pattern 942 and a second conductive pattern 944 formed on a top surface of the submount 940 through conductive adhesion layers 932 and 934.

The submount 940 may be formed of a material with excellent thermal conductivity. In some embodiments, the submount 940 may be formed of Si. However, a material for forming the submount 940 is not limited thereto.

The conductive adhesion layers 932 and 934 may be formed of a thin film or a stud bump. In some embodiments, the conductive adhesion layers 932 and 934 may be formed of Au, Sn, Ag, Cu, or a combination thereof. However, a material for forming the conductive adhesion layers 932 and 934 is not limited thereto.

In the semiconductor light-emitting device 900, light generated in the active layer 144 may be emitted without having constant directivity, and light emitted toward the substrate 110 may be extracted from the substrate 110 through the optical extraction film 120. As described in connection with FIGS. 2A to 8, the optical extraction film 120 may include at least one bonding layer having a refractive index between a refractive index of the substrate 110 and a refractive index of the nitride semiconductor thin film 130. In particular, from the nitride semiconductor thin film 130 to the substrate 110 through the optical extraction film 120, a refractive index difference between neighboring films is relatively small, and also, from the nitride semiconductor thin film 130 to the substrate 110, a refractive index sequentially changes. Accordingly, when light generated in the active layer 144 progresses from the nitride semiconductor thin film 130 to the substrate 110 through the optical extraction film 120, there is little possibility of the reflection of the light by total reflection caused by the refractive index difference. And, by reducing a pathway of light extracted from the nitride semiconductor thin film 130 to the outside through the substrate 110, optical loss may be suppressed and optical extraction efficiency may be improved.

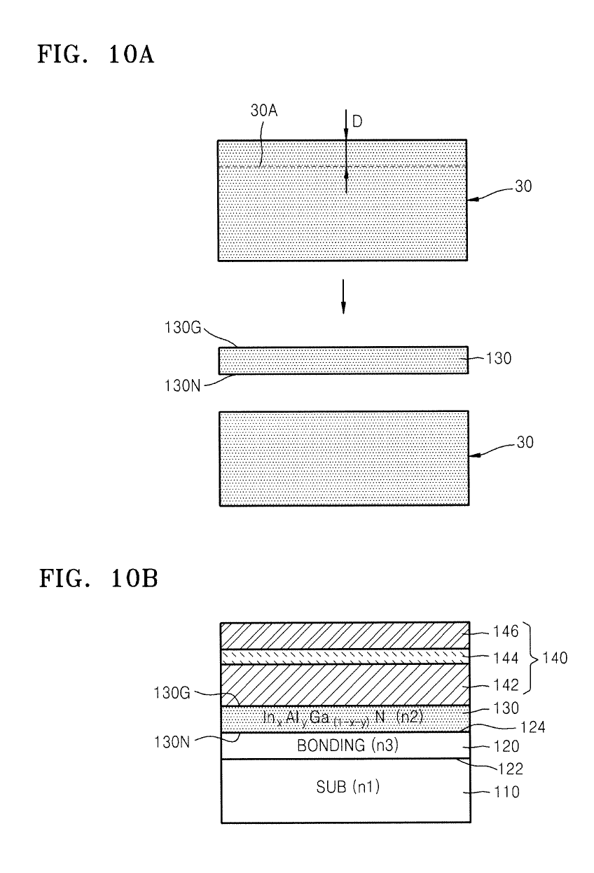

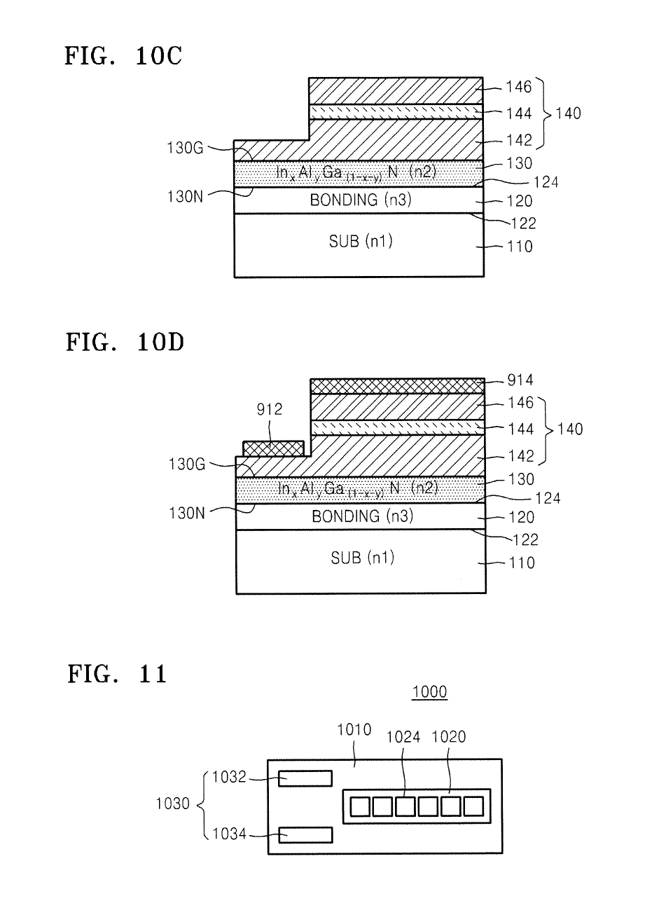

FIGS. 10A to 10D are cross-sectional views for explaining a process for forming the semiconductor light-emitting device 900, according to some embodiments of the present inventive concept. In FIGS. 10A to 10D, the same reference numerals denote the same elements as those shown in FIGS. 1 and 9, and accordingly, detailed description thereof will be omitted.

Referring to FIG. 10A, a nitride semiconductor monocrystalline bulk 30 is grown by hydride vapor phase epitaxy (HVPE), metal-organic chemical vapor deposition (MOCVD), or molecular beam epitaxy (MBE), and then, a portion of the nitride semiconductor monocrystalline bulk 30 is cut along a cut line 30A to separate into two partions, and the cut line 30A is polished to form a nitride semiconductor thin film 130 having a predetermined thickness.

The nitride semiconductor thin film 130 may have a thickness D of about 0.1 to 100 μm

In some embodiments, the nitride semiconductor monocrystalline bulk 30 may be formed of a GaN monocrystalline bulk. The nitride semiconductor thin film 130 formed of GaN may have an N surface (nitrogen atom surface) 130N, and a Ga surface (gallium atom surface) 130G that is opposite to the N surface 130N.

Referring to FIG. 10B, the substrate 110 that is a heterogeneous substrate having a chemical composition different from that in the nitride semiconductor thin film 130, and then, the optical extraction film 120 that includes at least one bonding layer with a refractive index n3 that is different from a refractive index of the nitride semiconductor thin film 130 is formed on the substrate 110, and the nitride semiconductor thin film 130 obtained by using the method explained in connection with FIG. 10A is bonded to the substrate 110 by using the optical extraction film 120 as an adhesive layer.

When the nitride semiconductor thin film 130 is formed of GaN, the nitride semiconductor thin film 130 is bonded to the optical extraction film 120 in such a way that the N surface 130N of the nitride semiconductor thin film 130 faces the top surface 124 of the optical extraction film 120.

Thereafter, the first conductive semiconductor layer 142, the active layer 144, and the second conductive semiconductor layer 146 are sequentially grown from the Ga surface 130G of the nitride semiconductor thin film 130 to form a light-emitting structure 140.

In some embodiments, the light-emitting structure 140 may be formed by MOCVD, HVPE, or MBE.

Referring to FIG. 10C, the light-emitting structure 140 is mesa-etched to expose a portion of the first conductive semiconductor layer 142.

Referring to FIG. 10D, the n-type electrode 912 is formed on the exposed portion of the first conductive semiconductor layer 142, and then, the p-type electrode 914 is formed on the second conductive semiconductor layer 146.

Thereafter, the n-type electrode 912 and the p-type electrode 914 are respectively connected to the first conductive pattern 942 and second conductive pattern 944 formed on the top surface of the submount 940 through the conductive adhesion layers 932 and 934, thereby obtaining the semiconductor light-emitting device 900 of FIG. 9.

FIG. 11 is a diagram illustrating a dimming system 1000 including a nitride semiconductor light-emitting device according to some embodiments of the present inventive concept.

Referring to FIG. 11, the dimming system 1000 includes a light-emitting module 1020 and a power supplier 1030 which are disposed on a structure 1010.

The light-emitting module 1020 includes a plurality of light-emitting device packages 1024. Each of the light-emitting device package 1024 may include at least one of the semiconductor light-emitting devices 100, 200, 300, and 400 which have been explained in connection with FIGS. 1 to 4.

The power supplier 1030 may include an interface 1032 through which power is input, and a power controller 1034 that controls power supplied to the light-emitting module 1020. The interface 1032 may include a fuse for blocking excess current and an electromagnetic wave shielding filter for shielding an electromagnetic wave glitch. The power controller 1034 may include a rectifying section and a soothing section that convert an alternate current input as power into a direct current, and a constant voltage controller for converting into a voltage appropriate for the light-emitting module 1020. The power supplier 1030 may include a feedback circuit apparatus that compares an intensity of light from the plurality of light-emitting device packages 1024 and an intensity of light that is set in advance, and a memory apparatus for storing information about, for example, target brightness or color rendering.

The dimming system 1000 may be used as an interior illumination, such as a backlight unit, a lamp, or a flat panel illumination used in a display apparatus, such as a liquid crystal display apparatus including an image panel, and an exterior illumination, such as street light, a sign, or a notice plane. Also, the dimming system 1000 may be used as an illumination device for various transportation means, for example, an illumination for vehicles, ships, or airplanes, and may be household appliances, such as TV, a refrigerator, or the like, or a medical device.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A semiconductor light-emitting device comprising:
a substrate having a first refractive index;
a nitride semiconductor layer disposed on the substrate and having a second refractive index that is different from the first refractive index;
a light-emitting structure disposed on the nitride semiconductor layer and including a first conductive semiconductor layer, an active layer, and a second conductive semiconductor layer; and
an optical extraction film disposed between the substrate and the nitride semiconductor layer and having a refractive index between the first refractive index and the second refractive index.

2. The semiconductor light-emitting device of claim 1, wherein:
the optical extraction film includes a plurality of bonding layers having different refractive indexes included in a range from the first refractive index to the second refractive index, and
the bonding layers are stacked from the substrate to the nitride semiconductor layer in such a sequence that a bonding layer with a larger refractive index is disposed closer to the nitride semiconductor layer.

3. The semiconductor light-emitting device of claim 1, wherein:
the first refractive index is smaller than the second refractive index,
the optical extraction film includes a plurality of bonding layers with different refractive indexes, and
the bonding layers are stacked from the substrate to the nitride semiconductor layer in such a sequence that a bonding layer with a larger refractive index is disposed closer to the nitride semiconductor layer.

4. The semiconductor light-emitting device of claim 3, wherein:
the bonding layers of the optical extraction film are stacked in such a way that a refractive index increases in the form of a step structure in a thickness direction of the optical extraction film from the substrate to the nitride semiconductor layer.

5. The semiconductor light-emitting device of claim 1, wherein:
the optical extraction film includes a plurality of bonding layers with different refractive indexes, and
the plurality of bonding layers includes:
a bottom surface bonding layer having the smallest refractive index among the plurality of bonding layers and contacts the substrate,
a top surface bonding layer having the largest refractive index among the plurality of bonding layers and being in contact with the nitride semiconductor layer, and
a middle bonding layer having a refractive index between a refractive index of the bottom surface bonding layer and a refractive index of the top surface bonding layer and being disposed between the bottom surface bonding layer and the top surface bonding layer.

6. The semiconductor light-emitting device of claim 5, wherein:
the bottom surface bonding layer, the top surface bonding layer, and the middle bonding layer have identical thicknesses.

7. The semiconductor light-emitting device of claim 5, wherein:
the bottom surface bonding layer, the top surface bonding layer, and the middle bonding layer have different thicknesses.

8. The semiconductor light-emitting device of claim 5, wherein:
from among the bottom surface bonding layer, the top surface bonding layer, and the middle bonding layer, the middle bonding layer has the largest thickness.

9. The semiconductor light-emitting device of claim 1, wherein:
the optical extraction film includes a plurality of bonding layers with different refractive indexes, and
at least one bonding layer of the plurality of bonding layers includes a plurality of island patterns that are spaced apart from each other.

10. The semiconductor light-emitting device of claim 1, wherein:
the optical extraction film includes a plurality of bonding layers with different refractive indexes, and
at least a portion of at least one of the bonding layers has an uneven pattern.

11. The semiconductor light-emitting device of claim 1, wherein:
the optical extraction film includes has a graded refractive index (GRI) bonding layer with a GRI.

12. The semiconductor light-emitting device of claim 11, wherein the GRI bonding layer comprises:
a TiₓSi₁₋ₓO_{y} film (0.05≦x≦0.95 and 0.2≦y≦2), a TiOₓ film (0.2≦x≦2), a SiOₓ film (0.2≦x≦2), or a combination thereof.

13. A semiconductor light-emitting device comprising:
a substrate;
an optical extraction film in contact with a surface of the substrate and including at least one bonding layer having a refractive index that is larger than a refractive index of the substrate;
a nitride semiconductor layer in contact with a surface of the optical extraction film and having a refractive index that is equal to or larger than a refractive index of a portion of the optical extraction film of which refractive index is the largest from among all the portions of the optical extraction film; and
a light-emitting structure disposed on the nitride semiconductor layer and including a first conductive semiconductor layer, an active layer, and a second conductive semiconductor layer.

14. The semiconductor light-emitting device of claim 13, wherein:
the optical extraction film includes a plurality of bonding layers with different refractive indexes included in a range that is larger than the refractive index of the substrate and is equal to or smaller than the refractive index of the nitride semiconductor layer, and
the plurality of bonding layers are stacked from the substrate to the nitride semiconductor layer in such a sequence that a bonding layer with a larger refractive index is disposed closer to the nitride semiconductor layer.

15. The semiconductor light-emitting device of claim 13, wherein:
the optical extraction film includes a graded refractive index (GRI) bonding layer with a GRI.

16. A dimming system comprising a semiconductor light-emitting device, the semiconductor light-emitting device including:
a substrate;
an optical extraction film being in contact with a surface of the substrate and including at least one bonding layer having a refractive index that is greater larger than a refractive index of the substrate;
a nitride semiconductor layer being in contact with a surface of the optical extraction film and having a refractive index that is equal to or greater larger than a refractive index of a portion of the optical extraction film of which refractive index is the largest from among all the portions of the optical extraction film; and
a light-emitting structure disposed on the nitride semiconductor layer and including a first conductive semiconductor layer, an active layer, and a second conductive semiconductor layer.

17. The system of claim 16, wherein the optical extraction film comprises a GRI bonding layer including:
a TiₓSi₁₋ₓO_{y} film (0.05≦x≦0.95 and 0.2≦y≦2), a TiOₓ film (0.2≦x≦2), a SiOₓ film (0.2≦x≦2), or a combination thereof.

18. The system of claim 16, wherein:
the optical extraction film includes a plurality of bonding layers with different refractive indexes, and
at least a portion of at least one of the bonding layers has an uneven pattern.

19. The system of claim 16, wherein:
the optical extraction film includes a plurality of bonding layers with different refractive indexes, and
at least one bonding layer of the plurality of bonding layers includes a plurality of island patterns that are spaced apart from each other.

20. The system of claim 18, wherein:
the plurality of bonding layers are stacked from the substrate to the nitride semiconductor layer in such a sequence that a bonding layer with a larger refractive index is disposed closer to the nitride semiconductor layer.
